(19) United States
(12) Patent Application Publication
(10) Pub. No.: US 2024/0250501 A1
(43) Pub. Date: Jul. 25, 2024

(54) SURFACE-EMITTING TYPE SEMICONDUCTOR LASER, OPTICAL TRANSMISSION APPARATUS, AND MANUFACTURING METHOD OF SURFACE-EMITTING TYPE SEMICONDUCTOR LASER

(71) Applicants: FUJIFILM BUSINESS INNOVATION CORP., Tokyo (JP); FUJIFILM CORPORATION, Tokyo (JP)

(72) Inventors: Naoya SEKITA, Kanagawa (JP); Takeshi MINAMIRU, Kanagawa (JP); Yuto IWANE, Kanagawa (JP); Koga MIZUNO, Kanagawa (JP); Kazutaka TAKEDA, Kanagawa (JP); Atsushi MUKAI, Kanagawa (JP)

(73) Assignees: FUJIFILM BUSINESS INNOVATION CORP., Tokyo (JP); FUJIFILM CORPORATION, Tokyo (JP)

(21) Appl. No.: 18/494,309

(22) Filed: Oct. 25, 2023

(30) Foreign Application Priority Data
Jan. 25, 2023 (JP) 2023-009631

(51) Int. Cl. H01S 5/183

(52) U.S. Cl. CPC H01S 5/18311; H01S 5/18347; H01S 5/1835; H01S 5/18361; H01S 5/18394

(57) ABSTRACT

A surface-emitting type semiconductor laser includes a substrate, and a structure that includes a first multilayer-film reflective mirror of a first conductivity type formed on the substrate, an active layer formed on the first multilayer-film reflective mirror, and a second multilayer-film reflective mirror of a second conductivity type that is formed on the active layer and includes a current confinement layer, and that is a structure in which a shape of an aperture formed in the current confinement layer to represent a part not subjected to oxide confinement is a shape not including an axially symmetrical or point symmetrical part.

### CROSS-REFERENCE TO RELATED APPLICATIONS

This application is based on and claims priority under 35 USC 119 from Japanese Patent Application No. 2023-009631 filed Jan. 25, 2023.

### BACKGROUND

### (i) Technical Field

The present invention relates to a surface-emitting type semiconductor laser, an optical transmission apparatus, and a manufacturing method of a surface-emitting type semiconductor laser.

### (ii) Related Art

For example, JP7087684B discloses a vertical cavity surface-emitting laser of which an aperture has an axially symmetrical shape. The vertical cavity surface-emitting laser is provided with a substrate having a major surface provided with a III-V compound semiconductor, and a semiconductor structure including a post having an active layer and a carrier confinement structure that are arranged in a direction of a first axis intersecting with the major surface of the substrate. The major surface of the substrate is a (001) surface, and the semiconductor structure is mounted on the substrate. The carrier confinement structure has a first region and a second region. The first region has specific electrical resistance that is lower than specific electrical resistance of the second region. The first region and the second region are arranged along a first reference surface intersecting with the direction of the first axis.

The first reference surface intersects with a second reference surface that extends in the direction of the first axis, in a first reference line segment connecting a first point and a second point on an edge of a cross section defined by an intersection between the first reference surface and the first region. The first reference line segment is one line segment among line segments of a first group connecting two points on the edge of the cross section and is not shorter than any other line segments among the line segments of the first group. The line segments of the first group extend in a [1-10] direction of the III-V compound semiconductor. The edge of the cross section has a first part and a second part divided by the first point and the second point.

The first reference line segment forms a right angle with a second reference line segment that connects a third point on the first part of the edge to a fourth point on the first reference line segment. The second reference line segment is one line segment forming a right angle with the first reference line segment among line segments of a second group connecting the third point and the fourth point and is not shorter than any other line segments among the line segments of the second group. The first reference line segment forms a right angle with a third reference line segment that connects a fifth point on the second part of the edge to a sixth point on the first reference line segment. The third reference line segment is one line segment forming a right angle with the first reference line segment among line segments of a third group connecting the fifth point and the sixth point and is not shorter than any other line segments among the line segments of the third group. The first reference line segment has a first length greater than a sum of a second length of the second reference line segment and a third length of the third reference line segment. The third length of the third reference line segment is less than the second length of the second reference line segment and greater than or equal to zero. The first reference line segment is positioned to set a value of the second length as low as possible. The edge of the cross section has a uniaxially symmetrical shape having a single axis of symmetry extending on the second reference line segment and on the third reference line segment. An edge of the post has a uniaxially symmetrical shape having a single axis of symmetry in a cross section along the first reference surface.

### SUMMARY

In the case of emitting light in multiple modes from the aperture, there has been found that presence of an axially symmetrical or point symmetrical part in the aperture may change modes (positions) oscillating from the aperture, that is, may cause mode switching. This is considered to be caused by presence of a plurality of locations having similar conditions of mode oscillation in a case where the aperture is axially symmetrical or point symmetrical. Accordingly, even in a case where oscillation is performed in a specific location, the oscillation is considered to change to oscillation in another location having a similar condition.

In a case where the mode switching occurs, optical output may be affected to cause deterioration of transmission quality, which is not beneficial.

Aspects of non-limiting embodiments of the present disclosure relate to a surface-emitting type semiconductor laser, an optical transmission apparatus, and a manufacturing method of a surface-emitting type semiconductor laser that can suppress occurrence of mode switching, compared to a case where an aperture formed in a current confinement layer of a multilayer-film reflective mirror has an axially symmetrical or point symmetrical shape.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a surface-emitting type semiconductor laser including a substrate, and a structure that includes a first multilayer-film reflective mirror of a first conductivity type formed on the substrate, an active layer formed on the first multilayer-film reflective mirror, and a second multilayer-film reflective mirror of a second conductivity type that is formed on the active layer and includes a current confinement layer, and that is a structure in which a shape of an aperture formed in the current confinement layer to represent a part not subjected to oxide confinement is a shape not including an axially symmetrical or point symmetrical part.

### BRIEF DESCRIPTION OF THE DRAWINGS

Exemplary embodiment(s) of the present invention will be described in detail based on the following figures, wherein:

FIG. 1A is a plan view illustrating an example of a configuration of a surface-emitting type semiconductor laser according to a first exemplary embodiment; FIG. 1B is a cross section view illustrating an example of the configuration of the surface-emitting type semiconductor laser according to the first exemplary embodiment;

FIG. 2 is a diagram for describing mode switching;

FIG. 3A is a plan view illustrating an example of a mesa structure provided in the surface-emitting type semiconductor laser according to the first exemplary embodiment; FIG. 3B is a cross section view in a case where the mesa structure illustrated in FIG. 3A is cut in a major axis direction; FIG. 3C is a cross section view in a case where the mesa structure illustrated in FIG. 3A is cut in a minor axis direction;

FIG. 4 is a diagram illustrating a relationship between a surface orientation and a crystal orientation of a GaAs substrate;

FIG. 5A is a plan view illustrating a mesa structure according to a comparative example; FIG. 5B is a plan view illustrating an example of a mesa structure not including a linear shape; FIG. 5C is a plan view illustrating an example of a mesa structure including a linear shape;

FIG. 6A is a diagram illustrating a mesa structure including an aperture of an elliptical shape; FIG. 6B is a diagram illustrating a mesa structure including an aperture of a rhombic shape;

FIG. 7 is a cross section view schematically illustrating an example of an aperture formation process according to the first exemplary embodiment;

FIG. 8 is a plan view and a cross section view illustrating an example of a manufacturing method of the surface-emitting type semiconductor laser according to the first exemplary embodiment;

FIG. 9 is a plan view and a cross section view illustrating an example of the manufacturing method of the surface-emitting type semiconductor laser according to the first exemplary embodiment;

FIG. 10 is a plan view and a cross section view illustrating an example of the manufacturing method of the surface-emitting type semiconductor laser according to the first exemplary embodiment;

FIG. 11A is a plan view illustrating an example of a trench structure provided in a surface-emitting type semiconductor laser according to a second exemplary embodiment; FIG. 11B is a cross section view in a case where the trench structure illustrated in FIG. 11A is cut in the major axis direction; FIG. 11C is a cross section view in a case where the trench structure illustrated in FIG. 11A is cut in the minor axis direction;

FIG. 12A is a plan view illustrating an example of a surface-emitting type semiconductor laser according to a third exemplary embodiment; FIG. 12B is a cross section view illustrating an example of a configuration of the surface-emitting type semiconductor laser according to the third exemplary embodiment;

FIG. 13A is a plan view illustrating an example of a mesa structure and a pedestal part according to the third exemplary embodiment; FIG. 13B is a plan view illustrating an example of the mesa structure, the pedestal part, and a metal film according to the third exemplary embodiment;

FIG. 14A is a plan view illustrating an example of the mesa structure, the pedestal part, the metal film, and a chip ID according to the third exemplary embodiment; FIG. 14B is a plan view illustrating an example of the mesa structure, the pedestal part, a plurality of metal films, and the chip ID according to the third exemplary embodiment;

FIGS. 15A and 15B are plan views illustrating a surface-emitting type semiconductor laser according to a comparative example; and

FIG. 16A is a plan view illustrating an example of a configuration of a surface-emitting type semiconductor laser according to a fourth exemplary embodiment; and FIG. 16B is a cross section view illustrating an example of the configuration of the surface-emitting type semiconductor laser according to the fourth exemplary embodiment.

### DETAILED DESCRIPTION

Hereinafter, exemplary embodiments of the technology of the present disclosure will be described in detail with reference to the drawings. Components and processing having identical operations, actions, and functions are designated by identical reference signs throughout the drawings, and redundant descriptions may be omitted as appropriate. Each drawing is merely a schematic illustration to the extent that the technology of the present disclosure can be fully understood. Thus, the technology of the present disclosure is not limited to only the illustrated examples. In addition, in the present exemplary embodiment, descriptions of configurations that are not directly related to the technology of the present disclosure and of well-known configurations may be omitted.

### First Exemplary Embodiment

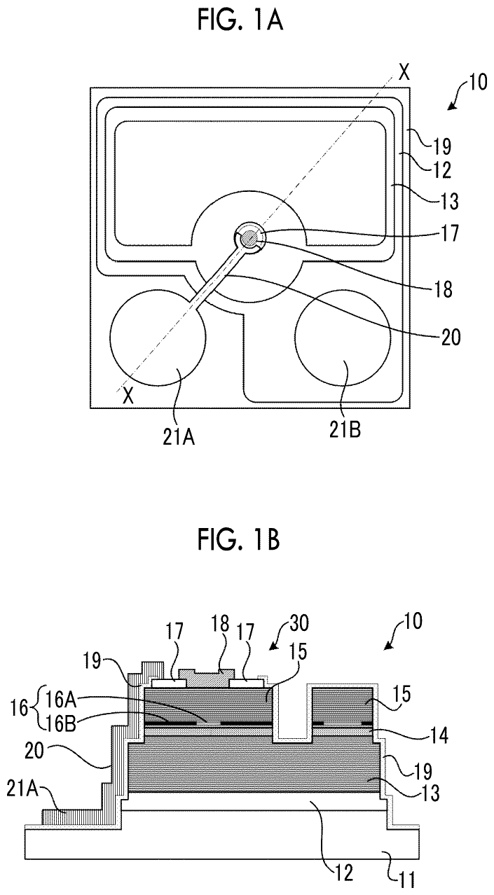

FIG. 1A is a plan view illustrating an example of a configuration of a surface-emitting type semiconductor laser 10 according to a first exemplary embodiment. FIG. 1B is a cross section view illustrating an example of the configuration of the surface-emitting type semiconductor laser 10 according to the first exemplary embodiment. FIG. 1B illustrates an XX cross section of FIG. 1A. The surface-emitting type semiconductor laser 10 according to the present exemplary embodiment is, for example, a vertical cavity surface-emitting laser (VCSEL). Hereinafter, a first conductivity type will be described as an n type, and a second conductivity type will be described as a p type. The first conductivity type may be configured as the p type, and the second conductivity type may be configured as the n type.

As illustrated in FIG. 1A and FIG. 1B, the surface-emitting type semiconductor laser 10 according to the present exemplary embodiment is configured to include a substrate 11, a contact layer 12, a first semiconductor multilayer-film reflective mirror 13, an active layer 14, and a second semiconductor multilayer-film reflective mirror 15. The first semiconductor multilayer-film reflective mirror 13 and the second semiconductor multilayer-film reflective mirror 15 are examples of a first multilayer-film reflective mirror and a second multilayer-film reflective mirror, respectively. While a multilayer-film reflective mirror is configured with a semiconductor in the present exemplary embodiment, a semiconductor laser may be configured as a whole, and the multilayer-film reflective mirror may be configured with a dielectric body.

In the surface-emitting type semiconductor laser 10, each configuration including the contact layer 12 formed on the substrate 11, the first semiconductor multilayer-film reflective mirror 13 formed on the contact layer 12, the active layer 14 formed on the first semiconductor multilayer-film reflective mirror 13, and the second semiconductor multilayer-film reflective mirror 15 that is formed on the active layer 14 and that includes a selective oxidation layer 16 forms a mesa structure 30 that is an example of a structure, and the mesa structure 30 constitutes a laser part. The selective oxidation layer 16 is an example of a current confinement layer. In addition to selective oxidation of current confinement, for example, current confinement may be performed by temporarily forming a pattern corresponding to an opening part in stacking a layered structure to selectively make a current easily pass to the opening part or by performing ion implantation to make the current not easily pass to a part subjected to ion implantation.

An interlayer insulation film 19 as an inorganic insulation film is deposited around a semiconductor layer including the mesa structure 30. The interlayer insulation film 19 extends from a side surface of the mesa structure 30 to a surface of the substrate 11 and is disposed below an electrode pad 21A. The interlayer insulation film 19 is formed of, for example, a silicon nitride film (SiN film). A material of the interlayer insulation film 19 is not limited to the silicon nitride film and may use, for example, a silicon oxide film (SiO₂ film) or a silicon oxynitride film (SiON film).

Wiring 20 is provided via an opening part of the interlayer insulation film 19. One end side of the wiring 20 is connected to a contact metal 17, and the other end side of the wiring 20 extends from the side surface of the mesa structure 30 to the surface of the substrate 11 and constitutes the electrode pad 21A on a p side.

A semi-insulating GaAs (gallium arsenide) substrate is used as the substrate 11. The semi-insulating GaAs substrate is a GaAs substrate not doped with impurities. The semi-insulating GaAs substrate has a very high resistivity, and a sheet resistance value of the substrate shows a value of approximately several MΩ. A material of the substrate 11 may be a material other than GaAs and may use, for example, gallium nitride (GaN) or indium phosphide (InP).

The contact layer 12 formed on the substrate 11 is formed of, for example, an n type GaAs layer doped with Si. The contact layer 12 is connected to the first semiconductor multilayer-film reflective mirror 13 of the n type to form an electrode pad 21B on an n side. The contact layer 12 has a function of applying a negative potential to the laser part configured with the mesa structure 30. The contact layer 12 may double as a buffer layer that is provided to achieve favorable crystallinity of the substrate surface after thermal cleaning.

The first semiconductor multilayer-film reflective mirror 13 of the n type formed on the contact layer 12 is configured as a lower distributed Bragg reflector (DBR). The first semiconductor multilayer-film reflective mirror 13 is a multilayer-film reflective mirror configured by alternately and repeatedly stacking two semiconductor films having different refractive indexes from each other. Specifically, the first semiconductor multilayer-film reflective mirror 13 is configured by alternately and repeatedly stacking a low refractive index film of the n type based on Al_{0.90}GaAs and a high refractive index film of the n type based on Al_{0.15}GaAs. A refractive index of Al_{0.90}GaAs of the n type is lower than a refractive index of Al_{0.15}GaAs of the n type. In the present exemplary embodiment, for example, 40 pairs of the low refractive index film and the high refractive index film are configured.

The active layer 14 formed on the first semiconductor multilayer-film reflective mirror 13 may be configured to include, for example, a lower spacer layer, a quantum well active layer, and an upper spacer layer (not illustrated). The active layer 14 functions as a resonator and has a function of adjusting a length of the resonator.

The second semiconductor multilayer-film reflective mirror 15 of the p type formed on the active layer 14 is configured as an upper DBR. The second semiconductor multilayer-film reflective mirror 15 is a multilayer-film reflective mirror configured by alternately and repeatedly stacking two semiconductor films having different refractive indexes from each other. Specifically, the second semiconductor multilayer-film reflective mirror 15 is configured by alternately and repeatedly stacking a low refractive index film of the p type based on Al_{0.90}GaAs and a high refractive index film of the p type based on Al_{0.15}GaAs. A refractive index (corresponds to a second refractive index) of Al_{0.90}GaAs of the p type is lower than a refractive index (corresponds to a first refractive index) of Al_{0.15}GaAs of the p type. In the present exemplary embodiment, for example, 22 pairs of the low refractive index film and the high refractive index film are configured. The Al_{0.15}GaAs film having a high refractive index is an example of a first film, and the Al_{0.90}GaAs film having a low refractive index is an example of a second film.

In addition, the second semiconductor multilayer-film reflective mirror 15 includes the selective oxidation layer 16. An amount of aluminum per unit amount of an aluminum-containing material forming the selective oxidation layer 16 is greater than an amount of aluminum per unit amount of an aluminum-containing material forming the second semiconductor multilayer-film reflective mirror 15. The selective oxidation layer 16 is formed of, for example, aluminum arsenide (AlAs) or of Al_{0.98}GaAs. The selective oxidation layer 16 is provided on the active layer 14. The selective oxidation layer 16 includes an aperture 16A representing a part not subjected to oxide confinement and an oxide-confined region 16B that is a region subjected to oxide confinement.

The contact metal 17 connected to the wiring 20 is formed on the second semiconductor multilayer-film reflective mirror 15. The contact metal 17 uses, for example, a stacked film of Ti/Au. In addition, an emission surface protective layer 18 that protects an emission surface of light is formed on the contact metal 17. The emission surface protective layer 18 is formed by depositing, for example, a silicon oxynitride film (SiON film). Not only the silicon oxynitride film (SiON film) but also a silicon nitride film (SiN film), a silicon oxide film (SiO₂film), or the like may be used.

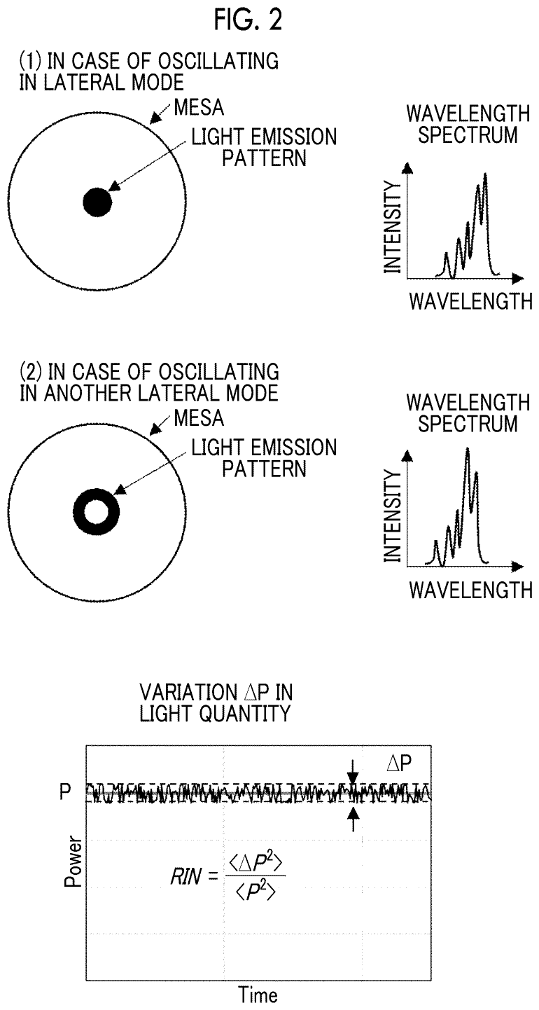

As described above, in the case of emitting light in multiple modes from the aperture, there has been found that presence of an axially symmetrical or point symmetrical part in the aperture may change modes (positions) oscillating from the aperture, that is, may cause mode switching. This mode switching will be described with reference to FIG. 2.

FIG. 2 is a diagram for describing the mode switching.

In FIGS. 2, (1) and (2) illustrate an image of a near field pattern (NFP) of the mode switching and a wavelength spectrum during oscillation. In (1), a light emission pattern in the case of oscillating in a lateral mode and a wavelength spectrum during oscillation are illustrated. In (2), a light emission pattern in the case of oscillating in another lateral mode and a wavelength spectrum during oscillation are illustrated. In a case where the mode switching occurs, the light emission pattern changes over time, and a phenomenon of a change in a peak wavelength occurs as illustrated in (1) and (2). In a case where a state change over time occurs because of the mode switching, this leads to a variation ΔP (P denotes intensity of light) in a light quantity over time and causes an increase in relative intensity noise (RIN) (=ΔP²/P²) denoting relative intensity noise.

Thus, in the surface-emitting type semiconductor laser 10 according to the present exemplary embodiment, a shape of the aperture 16A of the mesa structure 30 is set to be a shape not having an axially symmetrical or point symmetrical part. Accordingly, occurrence of the mode switching is suppressed, and an increase in the RIN is suppressed, compared to a case where the aperture 16A is set to have an axially symmetrical or point symmetrical shape.

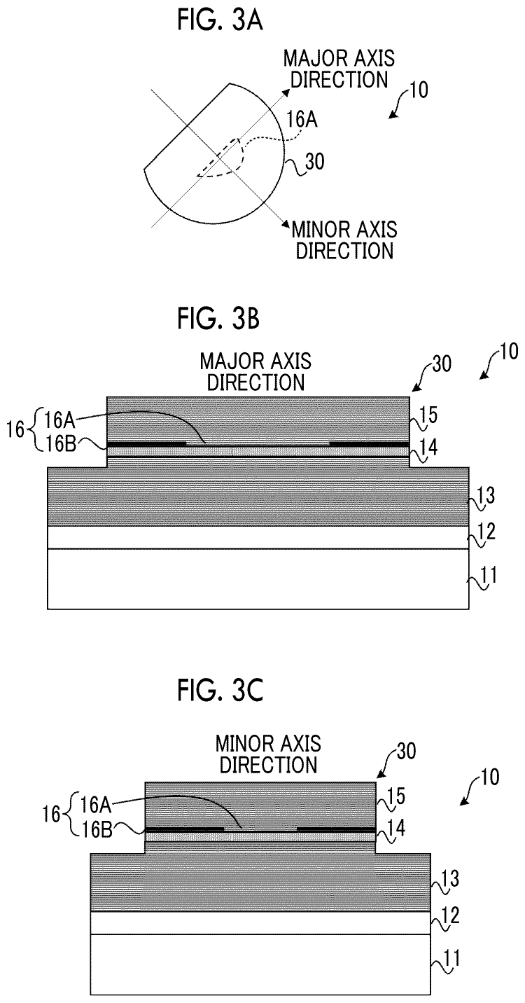

FIG. 3A is a plan view illustrating an example of the mesa structure 30 provided in the surface-emitting type semiconductor laser 10 according to the first exemplary embodiment. FIG. 3B is a cross section view in a case where the mesa structure 30 illustrated in FIG. 3A is cut in a major axis direction. FIG. 3C is a cross section view in a case where the mesa structure 30 illustrated in FIG. 3A is cut in a minor axis direction. The plan view and the cross section views are illustrated to be exaggerated with respect to an actual object for clear representation of the components, and scales between the drawings are assumed to not match.

As illustrated in FIG. 3A, the shape of the aperture 16A is set to be a shape not having an axially symmetrical or point symmetrical part. The shape of the aperture 16A is beneficially, for example, a shape of a partial ellipse. At this point, an external shape of the mesa structure 30 is not a so-called circular shape in which a whole outer circumference is configured as a perfect circle or as an ellipse. Specifically, the external shape of the mesa structure 30 includes, for example, a linear shape.

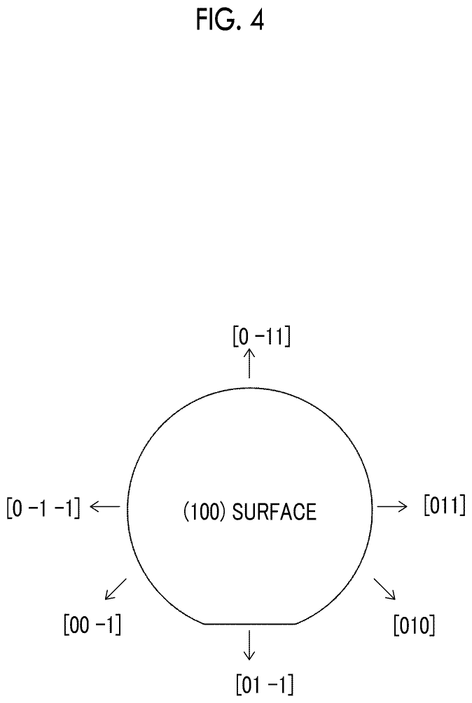

FIG. 4 is a diagram illustrating a relationship between a surface orientation and a crystal orientation of a GaAs substrate.

As illustrated in FIG. 4, the surface-emitting type semiconductor laser 10 according to the present exemplary embodiment is formed on a (100) surface of the GaAs substrate. An orientation flat of the GaAs substrate is a (01-1) surface, and the crystal orientation has the relationship illustrated in FIG. 4.

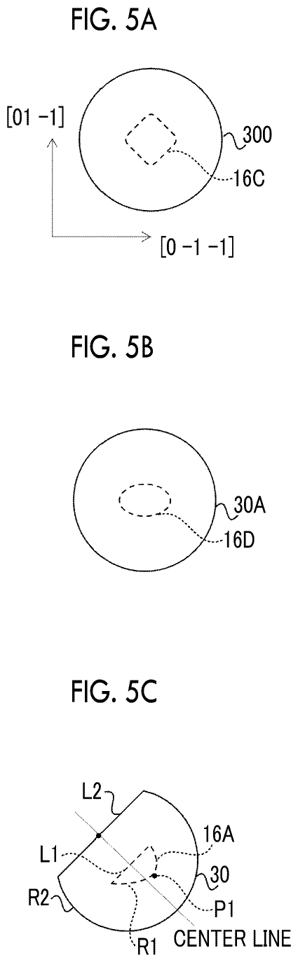

FIG. 5A is a plan view illustrating a mesa structure 300 according to a comparative example. FIG. 5B is a plan view illustrating an example of a mesa structure 30A not including a linear shape. FIG. 5C is a plan view illustrating an example of the mesa structure 30 including a linear shape. In FIG. 5A, [01-1] and [0-1-1] indicate the crystal orientation of the GaAs substrate.

The mesa structure 300 illustrated in FIG. 5A is a circular shape mesa (for example, a perfect circle mesa). In the mesa structure 300, a thickness of the selective oxidation layer is greater than or equal to 20 nm. Thus, an oxidation rate in a [01-1] direction (longitudinal direction) and an oxidation rate in a [0-1-1] direction (lateral direction) are approximately identical to each other. Thus, a shape of an aperture 16C with respect to the circular shape mesa is an isotropic and axially symmetrical shape. In this structure, the mode switching occurs, and the RIN is increased.

The mesa structure 30A illustrated in FIG. 5B is a circular shape mesa (for example, a perfect circle mesa). In the mesa structure 30A, the film thickness of the selective oxidation layer is less than a film thickness of any film that is the thinner of the Al_{0.15}GaAs film having a high refractive index and the Al_{0.90}GaAs film having a low refractive index. Specifically, the film thickness of the selective oxidation layer is, for example, less than 20 nm and is beneficially 15 nm.

In addition, the film thickness of the selective oxidation layer may be a film thickness with which a difference between the oxidation rates caused by the crystal orientation of the semiconductor layer formed on the GaAs substrate is increased to a certain level or higher. For example, in a case where the surface orientation of the GaAs substrate is the (100) surface, the oxidation rate is lower in the [0-1-1] direction than in a [0-11] direction, and the major axis direction of the aperture not having axial symmetry is beneficially a [00-1] direction.

According to the above, the difference between the oxidation rate in the longitudinal direction and the oxidation rate in the lateral direction can be increased with respect to the selective oxidation layer. Thus, a shape of an aperture 16D with respect to the circular shape mesa is an anisotropic and axially symmetrical shape. That is, since the difference between the oxidation rate in the longitudinal direction and the oxidation rate in the lateral direction is increased with respect to the selective oxidation layer, the shape of the aperture 16D is not a circular shape or a square shape and is an elliptical shape or a rhombic shape. The difference in a longitudinal-to-lateral ratio is, for example, greater than or equal to 5% and less than or equal to 15% and beneficially 10%.

In the mesa structure 30A illustrated in FIG. 5B, occurrence of the mode switching is suppressed, and an increase in the RIN is suppressed, compared to the mesa structure 300 illustrated in FIG. 5A.

In the mesa structure 30 illustrated in FIG. 5C, the film thickness of the selective oxidation layer is less than a film thickness of any film that is the thinner of the Al_{0.15}GaAs film having a high refractive index and the Al_{0.90}GaAs film having a low refractive index, as in the mesa structure 30A. Furthermore, the external shape of the mesa structure 30 is set to be a shape that includes a line segment shape and that is not a circular shape. In other words, the mesa structure 30 has a shape obtained by including a line segment shape in an external shape of the mesa structure 30A. That is, by setting a mesa to have an anisotropic shape having a major and a minor axis and by setting the major axis to be in the [00-1] direction, not only the difference between the oxidation rate in the longitudinal direction and the oxidation rate in the lateral direction is increased, but also the anisotropic shape of the mesa is added. Accordingly, the aperture 16A can be set to have an asymmetrical shape not having an axially symmetrical or point symmetrical part.

The shape of the aperture 16A illustrated in FIG. 5C is set to be a shape having a linear part L1 and an arc part R1 connected to both ends of the linear part L1. A point P1 that is most separated from the linear part L1 among a plurality of points constituting the arc part R1 is not on a center line that is orthogonal to a line segment L2 representing the linear shape included in the external shape of the mesa structure 30 and that passes through a center of the line segment L2.

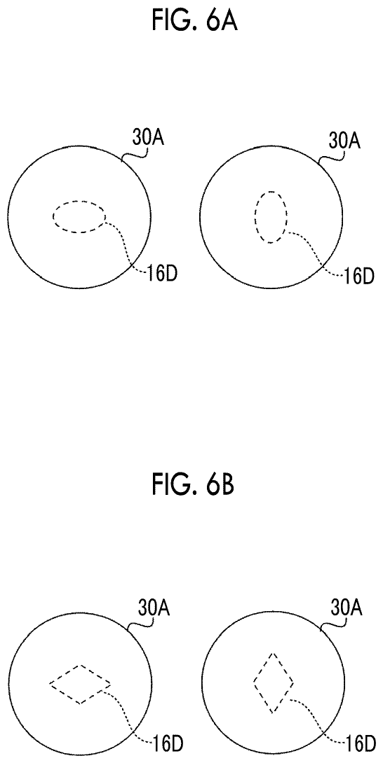

FIG. 6A is a diagram illustrating the mesa structure 30A having the aperture 16D of an elliptical shape. FIG. 6B is a diagram illustrating the mesa structure 30A having the aperture 16D of a rhombic shape.

As illustrated in FIG. 6A, the aperture shape of the elliptical shape with respect to the circular shape mesa may have a difference of 90° in a relationship of the major axis/minor axis. In addition, as long as the aperture shape is a shape of a distorted circle, the aperture shape may not be an elliptical shape or may be set to be a rhombic shape as illustrated in FIG. 6B. In the case of the rhombic shape, corners may be rounded.

Here, the relationship of the major axis/minor axis can be controlled using the crystal orientation of the GaAs substrate and a direction of the major axis of the mesa. For example, even in forming the surface-emitting type semiconductor laser 10 on the identical (100) surface of the GaAs substrate, in a case where the orientation flat of the GaAs substrate is a (0-1-1) surface, a relationship of a rotation of 90° from the crystal orientation illustrated in FIG. 4 is established. Thus, a shape in which a direction of the aperture of the circular shape mesa with respect to the orientation flat of the GaAs substrate is rotated by 90° is achieved.

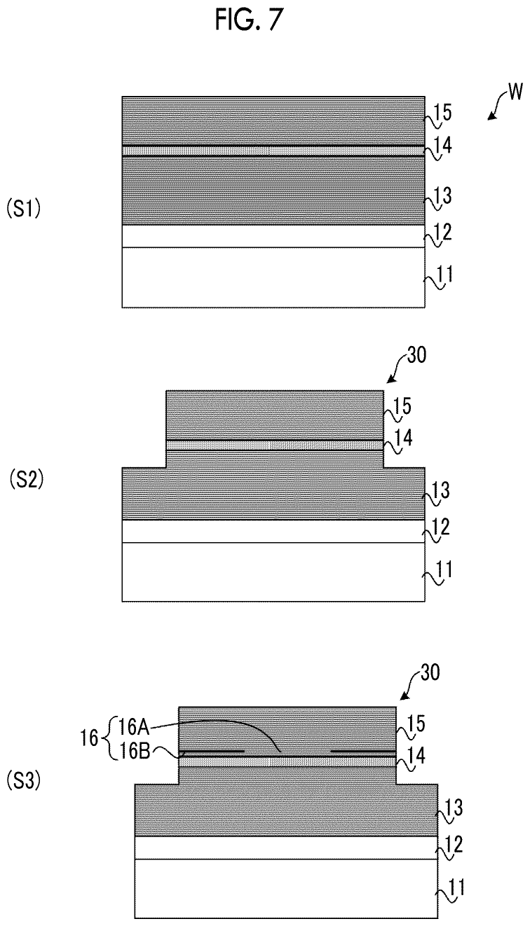

FIG. 7 is a cross section view schematically illustrating an example of an aperture formation process according to the first exemplary embodiment.

In (S1), a cross section of a VCSEL wafer W before processing is illustrated. The VCSEL wafer W is configured to include the substrate 11, the contact layer 12 formed on the substrate 11, the first semiconductor multilayer-film reflective mirror 13 formed on the contact layer 12, the active layer 14 formed on the first semiconductor multilayer-film reflective mirror 13, and the second semiconductor multilayer-film reflective mirror 15 formed on the active layer 14.

In (S2), the mesa structure 30 is formed by performing dry etching with respect to the VCSEL wafer W.

In (S3), the selective oxidation layer 16 including the aperture 16A and an oxide-confined region 16B is formed by performing, for example, steam oxidation processing with respect to the mesa structure 30.

Here, the oxidation rate is known to be different depending on the crystal orientation. In the present exemplary embodiment, the shape of the aperture 16A is controlled using the film thickness of the selective oxidation layer 16 and a change in the difference between the oxidation rates of the selective oxidation layer 16 with respect to the crystal orientation depending on Al composition.

In the case of the VCSEL, the substrate 11 uses GaAs, and the second semiconductor multilayer-film reflective mirror 15 uses at least two types of AlGaAs having different refractive indexes. The selective oxidation layer 16 for forming the aperture 16A is included in a part of the second semiconductor multilayer-film reflective mirror 15. The selective oxidation layer 16 is a layer having higher Al composition than AlGaAs forming the second semiconductor multilayer-film reflective mirror 15. For example, in the case of forming the second semiconductor multilayer-film reflective mirror 15 of a pair of Al_{0.9}GaAs having Al composition of 90% and Al_{0.15}GaAs having Al composition of 15%, the selective oxidation layer 16 uses, for example, AlAs or Al_{0.98}GaAs.

The aperture 16A is formed by etching the semiconductor stack structure to form the mesa and then performing steam oxidation. Since the selective oxidation layer 16 having high Al composition has a higher oxidation rate than other layers, only this layer is selectively oxidized to form the aperture 16A.

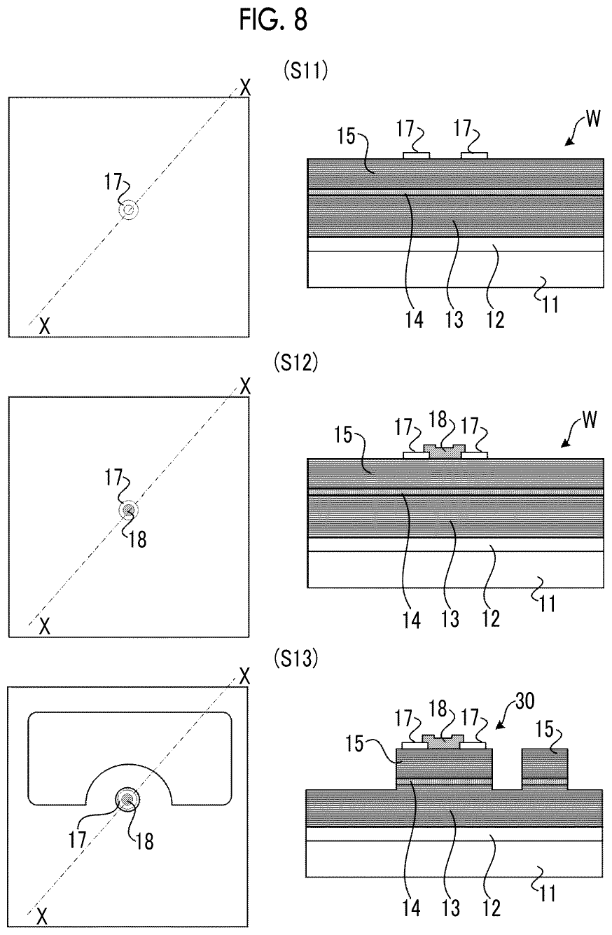

Next, a manufacturing method of the surface-emitting type semiconductor laser 10 according to the first exemplary embodiment will be specifically described with reference to FIG. 8 to FIG. 10. While a plurality of surface-emitting type semiconductor lasers 10 are formed on one wafer in the present exemplary embodiment, one of the surface-emitting type semiconductor lasers 10 will be illustrated and described below.

FIG. 8 to FIG. 10 are plan views and cross section views illustrating an example of the manufacturing method of the surface-emitting type semiconductor laser 10 according to the first exemplary embodiment. In FIG. 8 to FIG. 10, the cross section views illustrate an XX cross section of the plan views. The plan views and the cross section views are illustrated to be exaggerated with respect to an actual object for clear representation of the components, and scales between the drawings are assumed to not match.

In (S11) in FIG. 8, first, the VCSEL wafer W is prepared by epitaxially growing the contact layer 12 of the n type, the first semiconductor multilayer-film reflective mirror 13 of the n type, the active layer 14, and the second semiconductor multilayer-film reflective mirror 15 of the p type in this order on the substrate 11 of semi-insulating GaAs. The second semiconductor multilayer-film reflective mirror 15 includes the selective oxidation layer 16 (not illustrated). As described above, the film thickness of the selective oxidation layer 16 is less than the film thickness of any film that is the thinner of the Al_{0.15}GaAs film having a high refractive index and the Al_{0.90}GaAs film having a low refractive index constituting the second semiconductor multilayer-film reflective mirror 15. Specifically, the film thickness of the selective oxidation layer 16 is, for example, less than 20 nm and is beneficially 15 nm. Next, the contact metal 17 is formed on a wafer surface of the VCSEL wafer W. Specifically, the contact metal 17 is formed by depositing an electrode material on the epitaxially grown wafer surface and then performing dry etching on the deposited electrode material using a mask based on, for example, photolithography. The contact metal 17 is formed using, for example, a stacked film of Ti/Au.

In (S12), the emission surface protective layer 18 is formed by depositing a material to be used as the emission surface protective layer on the wafer surface and then performing dry etching on the deposited material using a mask based on, for example, photolithography. The material of the emission surface protective layer 18 uses, for example, a silicon nitride film.

In (S13), the mesa structure 30 is formed by forming a mask on the wafer surface using photolithography and etching and performing dry etching on a part including the second semiconductor multilayer-film reflective mirror 15 and the active layer 14 using the formed mask. That is, for example, the external shape of the mesa structure 30 is formed to be a shape that includes a linear shape and that is not a circular shape, as illustrated in FIG. 3A.

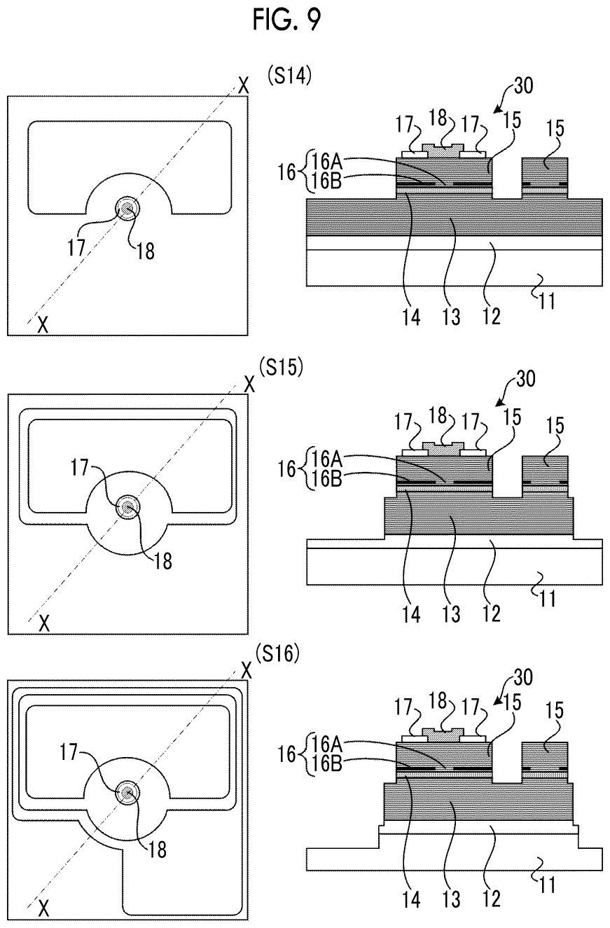

In (S14) in FIG. 9, the aperture 16A and the oxide-confined region 16B are formed in the mesa structure 30 by performing, for example, steam oxidation processing on the wafer to selectively oxidize the selective oxidation layer 16 from the side surface. The oxide-confined region 16B is a region that is oxidized by oxidation processing, and the aperture 16A is a current injection region that is left without being oxidized. That is, for example, the selective oxidation layer 16 is oxidized such that the shape of the aperture 16A is a shape not having an axially symmetrical or point symmetrical part, as illustrated in FIG. 3A. More specifically, the aperture 16A is set to have a shape of a partial ellipse. The aperture 16A narrows a current flowing between a p side electrode and an n side electrode (not illustrated) of the surface-emitting type semiconductor laser 10 and, for example, controls the lateral mode in oscillation of the surface-emitting type semiconductor laser 10.

That is, the mesa structure 30 is set in advance to have a layered structure in which the aperture 16A has an elliptical shape or a rhombic shape through oxidation. Then, in (S13), the external shape of the mesa structure 30 is set to be a shape that includes a linear shape and that is not a circular shape. Then, in (S14), the shape of the aperture 16A is set to be a shape not having an axially symmetrical or point symmetrical part by oxidizing the selective oxidation layer 16.

In (S15), the mesa structure 30 is formed by forming a mask on the wafer surface using photolithography and etching and performing dry etching on a part including the first semiconductor multilayer-film reflective mirror 13 using the formed mask.

In (S16), the mesa structure 30 is formed by forming a mask on the wafer surface using photolithography and etching and performing dry etching on the contact layer 12 using the formed mask.

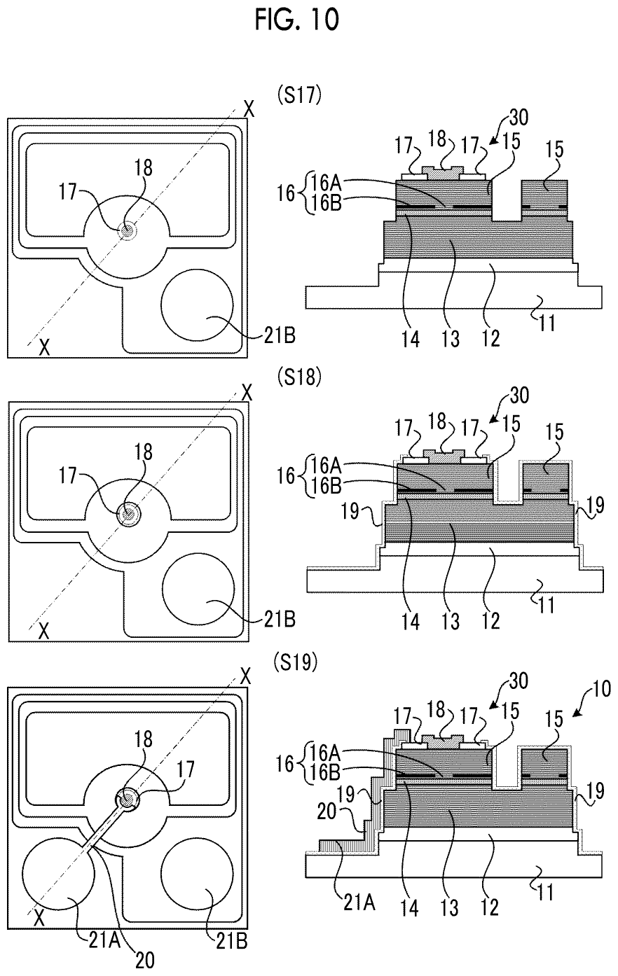

In (S17) in FIG. 10, the electrode pad 21B as an n side electrode is formed by depositing an electrode material on the contact layer 12 and then performing dry etching on the deposited material using a mask based on, for example, photolithography. The electrode pad 21B is formed using, for example, a stacked film of Ti/AuGe/Au.

In (S18), the interlayer insulation film 19 based on a silicon nitride film is deposited on a region of the wafer excluding the emission surface protective layer 18, the contact metal 17, and the electrode pad 21B. Specifically, the interlayer insulation film 19 is formed on the region of the wafer excluding the emission surface protective layer 18, the contact metal 17, and the electrode pad 21B by depositing the interlayer insulation film 19 on the wafer surface and then performing dry etching on the deposited interlayer insulation film 19 using a mask based on, for example, photolithography.

In (S19), the wiring 20 and the electrode pad 21A on the p side are formed by depositing an electrode material on the wafer surface and then performing dry etching on the deposited electrode material using a mask based on, for example, photolithography. The wiring 20 and the electrode pad 21A on the p side are formed using, for example, a stacked film of Ti/Au. The wiring 20 on the p side is connected to the contact metal 17 through the present process. While formation of patterns of the electrode material (the contact metal, the electrode pad, and the wiring) by performing dry etching using the mask based on photolithography has been described above, the patterns may be formed by forming the mask based on photolithography, then depositing the electrode material on the wafer surface, and performing lift-off processing.

Next, the surface-emitting type semiconductor laser 10 is separated into individual pieces by dicing in a dicing region, not illustrated. The surface-emitting type semiconductor laser 10 provided with the mesa structure 30 according to the present exemplary embodiment is manufactured through the above process.

The exemplary embodiment of the surface-emitting type semiconductor laser 10 has been described above. The exemplary embodiment may be in the form of an optical transmission apparatus provided with the surface-emitting type semiconductor laser 10. This optical transmission apparatus is provided with an optical transmission unit (not illustrated) that transmits light output from the surface-emitting type semiconductor laser 10.

According to the present exemplary embodiment, the shape of the aperture of the mesa structure is set to be a shape not having an axially symmetrical or point symmetrical part. Accordingly, occurrence of the mode switching is suppressed, and an increase in the RIN is suppressed, compared to a case where the aperture is set to have an axially symmetrical or point symmetrical shape.

### Second Exemplary Embodiment

The form of forming the aperture shape not having an axially symmetrical or point symmetrical part using the mesa has been described in the first exemplary embodiment. A form of forming the aperture shape not having an axially symmetrical or point symmetrical part using a trench will be described in a second exemplary embodiment.

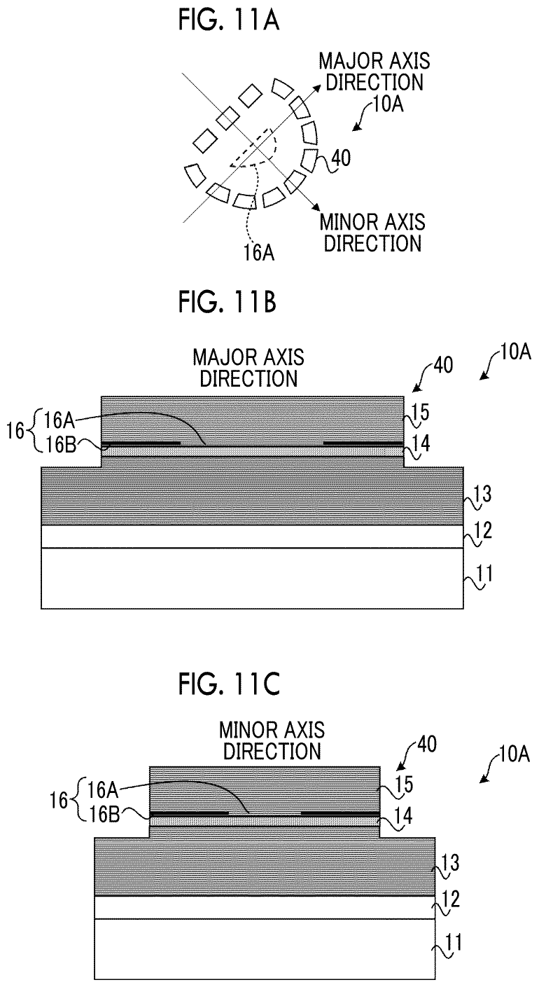

FIG. 11A is a plan view illustrating an example of a trench structure 40 provided in a surface-emitting type semiconductor laser 10A according to the second exemplary embodiment. FIG. 11B is a cross section view in a case where the trench structure 40 illustrated in FIG. 11A is cut in the major axis direction. FIG. 11C is a cross section view in a case where the trench structure 40 illustrated in FIG. 11A is cut in the minor axis direction. The plan view and the cross section views are illustrated to be exaggerated with respect to an actual object for clear representation of the components, and scales between the drawings are assumed to not match.

As illustrated in FIG. 11A, the shape of the aperture 16A is set to be a shape not having an axially symmetrical or point symmetrical part, as in the case of the mesa structure 30 according to the first exemplary embodiment. The shape of the aperture 16A is beneficially, for example, a shape of a partial ellipse. In the present exemplary embodiment, the shape of the aperture 16A is formed using the trench structure 40 instead of the mesa structure 30. That is, the external shape of the mesa structure 30 is formed as an arrangement of holes (trenches) of the trench structure 40. Specifically, the arrangement of the holes of the trench structure 40 is set to have, for example, a shape that includes a linear shape and that is not a circular shape.

For example, areas of a plurality of holes constituting the trench structure 40 are beneficially identical to each other. In a case where the areas (that is, surface areas) of the holes are not identical to each other, variations in a depth may occur because of etching. Thus, for example, the areas of the holes are beneficially set to be identical to each other. Shapes of the holes may not be identical to each other as long as the areas of the holes are identical to each other. The term “identical” here is not limited to complete identicalness and may indicate approximate identicalness including a predetermined error.

In addition, in the case of forming the trench structure 40, a plurality of holes are beneficially disposed at, for example, positions that are not axially symmetrical with each other.

According to the present exemplary embodiment, the shape of the aperture of the trench structure is set to be a shape not having an axially symmetrical or point symmetrical part. Accordingly, occurrence of the mode switching is suppressed, and an increase in the RIN is suppressed, compared to a case where the aperture is set to have an axially symmetrical or point symmetrical shape.

### Third Exemplary Embodiment

In a third exemplary embodiment, a form of a surface-emitting type semiconductor laser provided with an emission surface distortion suppression structure that can suppress distortion of the emission surface of the mesa structure will be described.

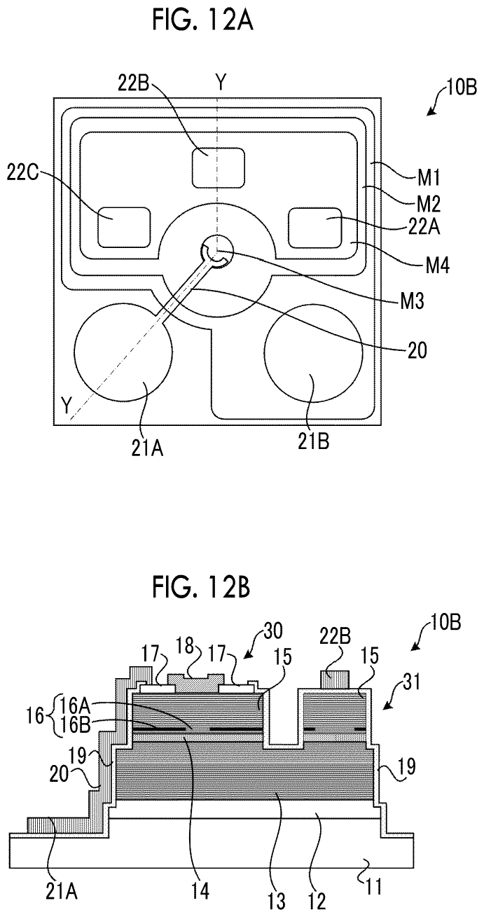

FIG. 12A is a plan view illustrating an example of a configuration of a surface-emitting type semiconductor laser 10B according to the third exemplary embodiment. FIG. 12B is a cross section view illustrating an example of the configuration of the surface-emitting type semiconductor laser 10B according to the third exemplary embodiment. FIG. 12B illustrates a YY cross section of FIG. 12A. While the mesa structure 30 according to the present exemplary embodiment will be described as a mesa of a circular shape, the shape of the mesa is not limited to the circular shape. In addition, the aperture 16A may be set to have an asymmetrical shape not having an axially symmetrical or point symmetrical part or may be set to have a shape including an axially symmetrical or point symmetrical part.

As illustrated in FIG. 12A and FIG. 12B, the surface-emitting type semiconductor laser 10B according to the present exemplary embodiment is provided with an n type contact layer pattern M1, an n type DBR layer pattern M2, an emission unit pattern M3, and an emission unit protective pattern M4. The n type contact layer pattern M1 is a pattern that corresponds to the contact layer 12 and that includes the electrode pad 21B. The n type DBR layer pattern M2 is a pattern that corresponds to the first semiconductor multilayer-film reflective mirror 13. The emission unit pattern M3 is a pattern that corresponds to the contact metal 17, the emission surface protective layer 18, and the wiring 20. The emission unit protective pattern M4 is a pattern that corresponds to metal films 22A to 22C. In addition, the electrode pad 21A is connected to the contact metal 17 via the wiring 20 and is formed on the substrate 11.

Both of the electrode pads 21A and 21B are formed on a chip surface. In addition, both of the electrode pads 21A and 21B are formed at lower positions than an uppermost part (emission surface) of the mesa structure 30. By forming both of the electrode pads 21A and 21B at lower positions than the emission surface, pad damage during a rear surface process is avoided. However, in this type of structure, the emission surface is subjected to a load in a process of thinning the wafer through polishing, grinding, or the like, and the emission surface may be distorted. In a case where the emission surface is distorted, a light emission unit and wiring around the light emission unit may be subjected to a load and be deformed.

Thus, the surface-emitting type semiconductor laser 10B according to the present exemplary embodiment is provided with a pedestal part 31 as a semiconductor region. The pedestal part 31 includes the active layer 14, the selective oxidation layer 16, the second semiconductor multilayer-film reflective mirror 15, and the interlayer insulation film 19. The pedestal part 31 is formed next to the mesa structure 30. A height of the pedestal part 31 is set to be greater than or equal to a height of the mesa structure 30. In addition, the plurality of metal films 22A to 22C are formed on the pedestal part 31. A thickness of each of the plurality of metal films 22A to 22C is set to be greater than or equal to a thickness of the wiring 20 (hereinafter, referred to as a “wiring thickness”). At least one of the plurality of metal films 22A to 22C may be formed.

In addition, for example, an area of each of the metal films 22A to 22C is beneficially greater than an area of an upper end part of the wiring 20. In addition, for example, a distance between the upper end part of the wiring 20 and a chip center part (for example, a center of the contact metal 17) is beneficially shorter than a distance between each of the metal films 22A to 22C and the chip center part (for example, the center of the contact metal 17).

The above structure suppresses distortion of the emission surface. That is, the pedestal part 31 and the metal films 22A to 22C reduce a load on the wiring 20 and suppress a deformation, a short-circuit, and the like.

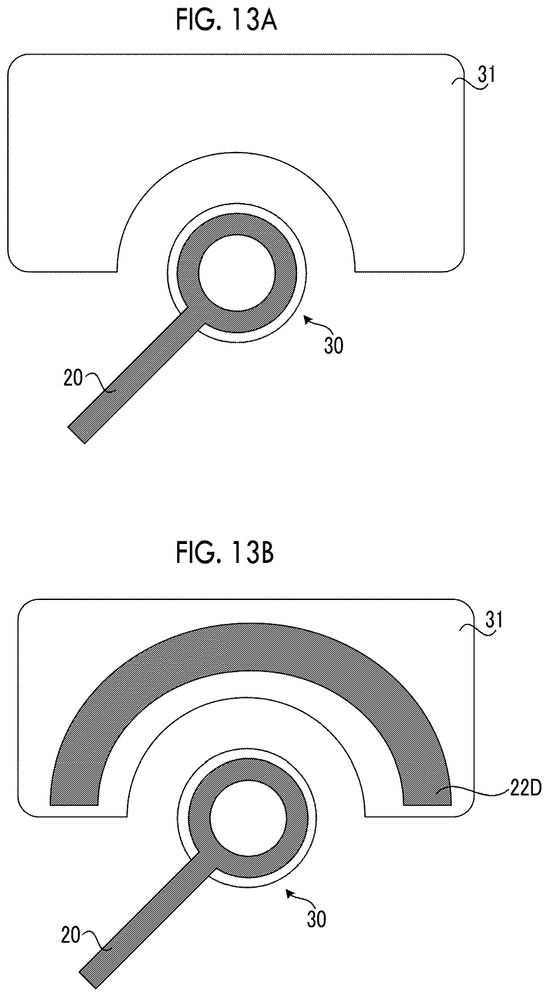

FIG. 13A is a plan view illustrating an example of the mesa structure 30 and the pedestal part 31 according to the third exemplary embodiment. FIG. 13B is a plan view illustrating an example of the mesa structure 30, the pedestal part 31, and a metal film 22D according to the third exemplary embodiment.

As illustrated in FIG. 13A, in the case of forming the emission surface, the pedestal part 31 that is a semiconductor region having the identical height to the mesa structure 30 is formed separately from the mesa structure 30. Furthermore, as illustrated in FIG. 13B, by forming the metal film 22D having the identical thickness to the wiring thickness on the pedestal part 31, a structure that does not affect characteristics can be formed at a position that is a position other than the emission surface and that is higher than the emission surface, and damage to the emission surface during the rear surface process can be avoided. The term “identical” here is not limited to complete identicalness and may indicate approximate identicalness including a predetermined error.

As illustrated in FIG. 13B, the pedestal part 31 having the identical height to the mesa structure 30 and the metal film 22D having the identical thickness to the wiring thickness are formed to surround the mesa structure 30. In the example in FIG. 13B, the metal film 22D of an arc shape is formed to surround ⅓ or more around the mesa structure 30. Accordingly, the load on the emission surface during the rear surface process is distributed, and damage is more effectively avoided.

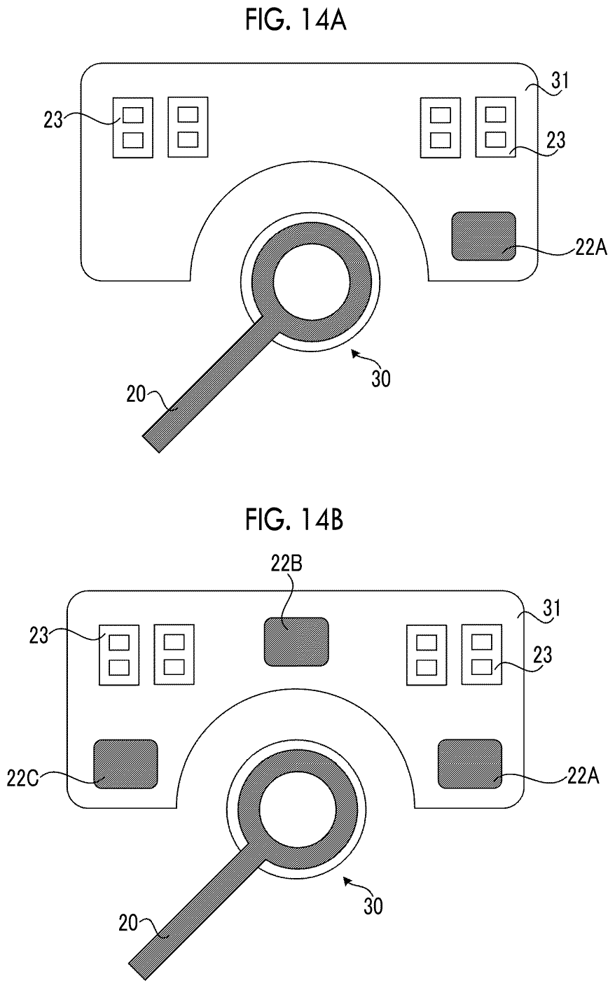

FIG. 14A is a plan view illustrating an example of the mesa structure 30, the pedestal part 31, the metal film 22A, and a chip ID 23 according to the third exemplary embodiment. FIG. 14B is a plan view illustrating an example of the mesa structure 30, the pedestal part 31, the plurality of metal films 22A to 22C, and the chip ID 23 according to the third exemplary embodiment.

As illustrated in FIG. 14A, one metal film 22A having the identical thickness to the wiring thickness may be formed on the pedestal part 31. The chip identification (ID) 23 for identifying a chip may be formed in a blank region of the pedestal part 31. Accordingly, the chip can be identified while a load on the mesa structure 30 during the rear surface process is distributed.

As illustrated in FIG. 14B, the plurality of metal films 22A to 22C having the identical thickness to the wiring thickness may be separately formed on the pedestal part 31 to surround the mesa structure 30. The chip ID 23 may be formed in a blank region formed by separating the plurality of metal films 22A to 22C from each other. Accordingly, as described above, the chip can be identified while the load on the mesa structure 30 during the rear surface process is distributed.

In forming, for example, a step exceeding 10 μm from the uppermost part of the mesa structure 30 to the electrode pad, in a case where the chip ID 23 formed to have the identical height to the uppermost part of the mesa has an isolated pattern of, for example, “8” or “0”, the isolated pattern may be skipped during patterning in a photolithography process, and the ID may not be identifiable. Therefore, the pattern may be notched so as not to be isolated. Accordingly, a formation failure is avoided, and an exterior failure is prevented.

According to the present exemplary embodiment, distortion of the emission surface is suppressed. That is, the pedestal part and the metal films reduce the load on the wiring and suppress a deformation, a short-circuit, and the like.

### Fourth Exemplary Embodiment

In a fourth exemplary embodiment, a form of a surface-emitting type semiconductor laser provided with a short circuit suppression structure that suppresses a short circuit of wiring connected to an electrode pad disposed in a lower layer of the mesa structure will be described.

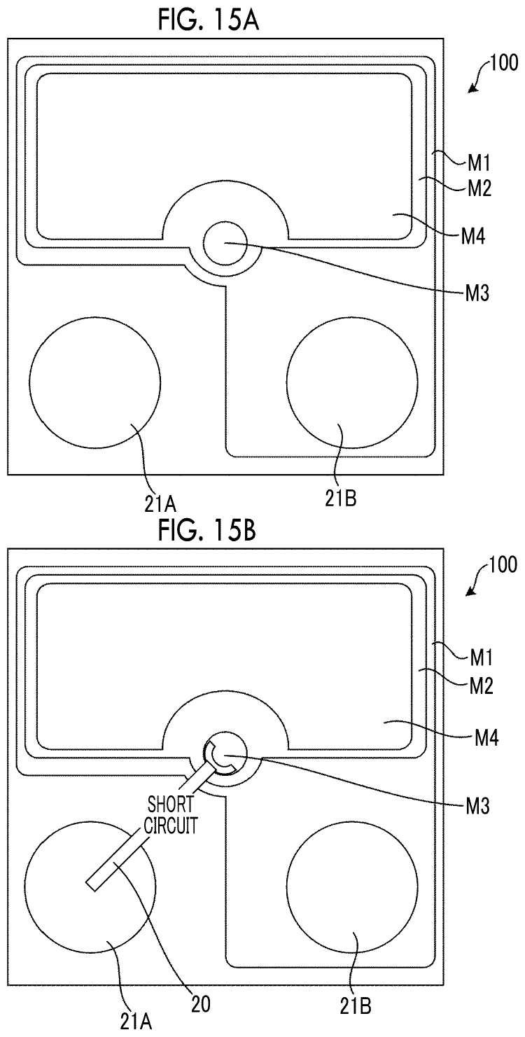

FIG. 15A and FIG. 15B are plan views illustrating a surface-emitting type semiconductor laser 100 according to a comparative example.

As illustrated in FIG. 15A and FIG. 15B, the surface-emitting type semiconductor laser 100 according to the comparative example is provided with the n type contact layer pattern M1, the n type DBR layer pattern M2, the emission unit pattern M3, and the emission unit protective pattern M4. As in the surface-emitting type semiconductor laser 10B illustrated in FIG. 12A and FIG. 12B, the n type contact layer pattern M1 is a pattern that corresponds to the contact layer 12 and that includes the electrode pad 21B. The n type DBR layer pattern M2 is a pattern that corresponds to the first semiconductor multilayer-film reflective mirror 13. The emission unit pattern M3 is a pattern that corresponds to the contact metal 17, the emission surface protective layer 18, and the wiring 20. The emission unit protective pattern M4 is a pattern that corresponds to the metal films 22A to 22C (not illustrated). In addition, the electrode pad 21A is connected to the contact metal 17 via the wiring 20 and is formed on the substrate 11.

Enlarging a region of the n type DBR layer pattern M2 can reduce resistance. However, in order to form the electrode pads 21A and 21B in the lower layer of the mesa, an area of the n type DBR layer pattern M2 is enlarged on a side opposite to the electrode pads 21A and 21B with respect to the mesa of the emission unit pattern M3. By forming the emission unit protective pattern M4 having the identical height to the emission unit pattern M3, the load on the emission surface of the emission unit pattern M3 generated during wafer fixation in the wafer rear surface process is reduced.

However, in the case of forming the wiring 20 from the uppermost part of the emission unit pattern M3 to the electrode pad 21A by forming the emission unit protective pattern M4 having the identical height to the emission unit pattern M3, a short circuit may occur in the wiring 20 formed on the identical surface to the electrode pad 21A.

In forming the wiring 20, a wiring pattern is patterned in the photolithography process with respect to the step of, for example, approximately 10 μm from the uppermost part of the emission unit pattern M3 to a pad surface. However, in resist application, a resist thickness is increased at a lower position of the step such as a pad formation position, and a resist is thinned at a high position on the emission unit. Thus, a fine pattern such as the wiring 20 is difficult to form at a low position of the step. For example, while improvement can be made by increasing a wiring width, wiring capacitance is increased, and responsiveness is decreased. This results in a disadvantage in terms of responsiveness.

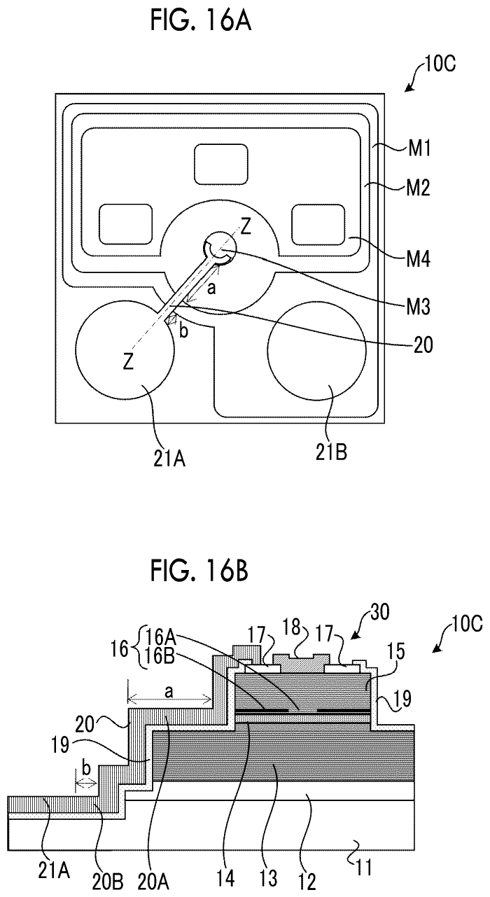

FIG. 16A is a plan view illustrating an example of a configuration of a surface-emitting type semiconductor laser 10C according to the fourth exemplary embodiment. FIG. 16B is a cross section view illustrating an example of the configuration of the surface-emitting type semiconductor laser 10C according to the fourth exemplary embodiment. FIG. 16B illustrates a ZZ cross section of FIG. 16A. While the mesa structure 30 according to the present exemplary embodiment will be described as a mesa of a circular shape, the shape of the mesa is not limited to the circular shape. In addition, the aperture 16A may be set to have an asymmetrical shape not having an axially symmetrical or point symmetrical part or may be set to have a shape including an axially symmetrical or point symmetrical part.

Regarding the above problem, in the surface-emitting type semiconductor laser 10C according to the present exemplary embodiment, the n type contact layer pattern M1 and the n type DBR layer pattern M2 are extended to a pad side to increase a wiring length a on an n type DBR surface and decrease a wiring length b on the pad surface, as illustrated in FIG. 16A and FIG. 16B. Accordingly, a short circuit failure on the pad surface is improved. For example, more beneficially, considering a semiconductor processing margin, the electrode pad 21A and the wiring 20 may be directly connected to each other by bringing the electrode pad 21A and a step part to each other as close as possible.

That is, the wiring length a of the wiring 20 formed on the first semiconductor multilayer-film reflective mirror 13 (n type DBR layer) is set to be longer than the wiring length b from the step part of the wiring 20 formed on the substrate 11 to the electrode pad 21A (a>b). The step part here is a step between the substrate 11 and the contact layer 12. Accordingly, a short circuit failure on the pad surface is improved.

In addition, by increasing an area of a part corresponding to the wiring length a compared to the comparative example illustrated in FIG. 15A and FIG. 15B, an area of the first semiconductor multilayer-film reflective mirror 13 (n type DBR layer) is increased. Thus, a current path is widened, and resistance is reduced.

While the surface-emitting type semiconductor laser based on GaAs using the semi-insulating GaAs substrate has been illustratively described in the exemplary embodiments, the present disclosure is not limited thereto and may be in the form of using a substrate based on gallium nitride (GaN) or a substrate based on indium phosphide (InP).

In addition, while the form of forming the contact layer of the n type on the substrate has been illustratively described in the exemplary embodiments, the present disclosure is not limited thereto and may be in the form of forming a contact layer of the p type on the substrate. In this case, the n type and the p type may be replaced with each other in reverse in the above description.

The following is further disclosed with respect to the above exemplary embodiments.

A surface-emitting type semiconductor laser according to (((1))) includes a substrate, and a structure that includes a first multilayer-film reflective mirror of a first conductivity type formed on the substrate, an active layer formed on the first multilayer-film reflective mirror, and a second multilayer-film reflective mirror of a second conductivity type that is formed on the active layer and includes a current confinement layer, and that is a structure in which a shape of an aperture formed in the current confinement layer to represent a part not subjected to oxide confinement is a shape not including an axially symmetrical or point symmetrical part.

A surface-emitting type semiconductor laser according to (((2))) is provided such that in the surface-emitting type semiconductor laser according to (((1))), the structure is a mesa structure or a trench structure, and an external shape of the mesa structure or an arrangement of holes of the trench structure is not a circular shape.

A surface-emitting type semiconductor laser according to (((3))) is provided such that in the surface-emitting type semiconductor laser according to (((2))), the external shape of the mesa structure or the arrangement of the holes of the trench structure includes a linear shape.

A surface-emitting type semiconductor laser according to (((4))) is provided such that in the surface-emitting type semiconductor laser according to (((3))), the shape of the aperture is a shape including a linear part and an arc part connected to both ends of the linear part, and a point most separated from the linear part among a plurality of points constituting the arc part is not on a center line that is orthogonal to a line segment representing the linear shape included in the external shape of the mesa structure or in the arrangement of the holes of the trench structure and that passes through a center of the line segment.

A surface-emitting type semiconductor laser according to (((5))) is provided such that in the surface-emitting type semiconductor laser according to any one of (((1))) to (((4))), the shape of the aperture is a shape of a partial ellipse.

A surface-emitting type semiconductor laser according to (((6))) is provided such that in the surface-emitting type semiconductor laser according to any one of (((1))) to (((5))), the structure is a trench structure, and areas of a plurality of holes constituting the trench structure are identical to each other.

A surface-emitting type semiconductor laser according to (((7))) is provided such that in the surface-emitting type semiconductor laser according to any one of (((1))) to (((6))), the second multilayer-film reflective mirror is obtained by alternately stacking a first film having a first refractive index and a second film having a second refractive index lower than the first refractive index, the current confinement layer is a selective oxidation layer, and a film thickness of the selective oxidation layer is less than a film thickness of any film that is the lesser of a film thickness of the first film and a film thickness of the second film.

A surface-emitting type semiconductor laser according to (((8))) is provided such that in the surface-emitting type semiconductor laser according to (((7))), the film thickness of the selective oxidation layer is less than 20 nm.

An optical transmission apparatus according to (((9))) includes the surface-emitting type semiconductor laser according to any one of (((1))) to (((8))), and an optical transmission unit that transmits light output from the surface-emitting type semiconductor laser.

A manufacturing method of a surface-emitting type semiconductor laser according to (((10))) includes forming a first multilayer-film reflective mirror of a first conductivity type on a substrate, forming an active layer on the first multilayer-film reflective mirror, forming a second multilayer-film reflective mirror of a second conductivity type including a current confinement layer on the active layer, forming an external shape or an arrangement of holes of a structure including the first multilayer-film reflective mirror, the active layer, and the second multilayer-film reflective mirror to be a shape that includes a linear shape and that is not a circular shape, and oxidizing the current confinement layer of the structure such that a shape of an aperture representing a part not subjected to oxide confinement is a shape not having an axially symmetrical or point symmetrical part.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A surface-emitting type semiconductor laser comprising:
a substrate; and
a structure that includes a first multilayer-film reflective mirror of a first conductivity type formed on the substrate, an active layer formed on the first multilayer-film reflective mirror, and a second multilayer-film reflective mirror of a second conductivity type that is formed on the active layer and includes a current confinement layer, and that is a structure in which a shape of an aperture formed in the current confinement layer to represent a part not subjected to oxide confinement is a shape not including an axially symmetrical or point symmetrical part.

2. The surface-emitting type semiconductor laser according to claim 1,
wherein the structure is a mesa structure or a trench structure, and
an external shape of the mesa structure or an arrangement of holes of the trench structure is not a circular shape.

3. The surface-emitting type semiconductor laser according to claim 2,
wherein the external shape of the mesa structure or the arrangement of the holes of the trench structure includes a linear shape.

4. The surface-emitting type semiconductor laser according to claim 3,
wherein the shape of the aperture is a shape including a linear part and an arc part connected to both ends of the linear part, and
a point most separated from the linear part among a plurality of points constituting the arc part is not on a center line that is orthogonal to a line segment representing the linear shape included in the external shape of the mesa structure or in the arrangement of the holes of the trench structure and that passes through a center of the line segment.

5. The surface-emitting type semiconductor laser according to claim 1,
wherein the shape of the aperture is a shape of a partial ellipse.

6. The surface-emitting type semiconductor laser according to claim 1,
wherein the structure is a trench structure, and
areas of a plurality of holes constituting the trench structure are identical to each other.

7. The surface-emitting type semiconductor laser according to claim 1,
wherein the second multilayer-film reflective mirror is obtained by alternately stacking a first film having a first refractive index and a second film having a second refractive index lower than the first refractive index,
the current confinement layer is a selective oxidation layer, and
a film thickness of the selective oxidation layer is less than a film thickness of any film that is the lesser of a film thickness of the first film and a film thickness of the second film.

8. The surface-emitting type semiconductor laser according to claim 7,
wherein the film thickness of the selective oxidation layer is less than 20 nm.

9. An optical transmission apparatus comprising:
the surface-emitting type semiconductor laser according to claim 1; and
an optical transmission unit that transmits light output from the surface-emitting type semiconductor laser.

10. An optical transmission apparatus comprising:
the surface-emitting type semiconductor laser according to claim 2; and
an optical transmission unit that transmits light output from the surface-emitting type semiconductor laser.

11. An optical transmission apparatus comprising:
the surface-emitting type semiconductor laser according to claim 3; and
an optical transmission unit that transmits light output from the surface-emitting type semiconductor laser.

12. An optical transmission apparatus comprising:
the surface-emitting type semiconductor laser according to claim 4; and
an optical transmission unit that transmits light output from the surface-emitting type semiconductor laser.

13. An optical transmission apparatus comprising:
the surface-emitting type semiconductor laser according to claim 5; and
an optical transmission unit that transmits light output from the surface-emitting type semiconductor laser.

14. An optical transmission apparatus comprising:
the surface-emitting type semiconductor laser according to claim 6; and
an optical transmission unit that transmits light output from the surface-emitting type semiconductor laser.

15. An optical transmission apparatus comprising:
the surface-emitting type semiconductor laser according to claim 7; and
an optical transmission unit that transmits light output from the surface-emitting type semiconductor laser.

16. An optical transmission apparatus comprising:
the surface-emitting type semiconductor laser according to claim 8; and
an optical transmission unit that transmits light output from the surface-emitting type semiconductor laser.

17. A manufacturing method of a surface-emitting type semiconductor laser, the manufacturing method comprising:
forming a first multilayer-film reflective mirror of a first conductivity type on a substrate;
forming an active layer on the first multilayer-film reflective mirror;
forming a second multilayer-film reflective mirror of a second conductivity type including a current confinement layer on the active layer;
forming an external shape or an arrangement of holes of a structure including the first multilayer-film reflective mirror, the active layer, and the second multilayer-film reflective mirror to be a shape that includes a linear shape and that is not a circular shape; and
oxidizing the current confinement layer of the structure such that a shape of an aperture representing a part not subjected to oxide confinement is a shape not having an axially symmetrical or point symmetrical part.
